(19) United States
(12) Patent Application Publication
(10) Pub. No.: US 2005/0211291 A1
(43) Pub. Date: Sep. 29, 2005

(54) Solar cell assembly

(75) Inventor: Maurice Peter Bianchi, Palos Verdes, CA (US)

Correspondence Address: SONNENSCHEIN NATH & ROSENTHAL LLP, P.O. BOX 061080, WACKER DRIVE STATION, SEARS TOWER, CHICAGO, IL, 60606-1080, US

(73) Assignee: The Boeing Company

(21) Appl. No.: 10/806,710

(22) Filed: Mar. 23, 2004

(51) Int. Cl. H01L 31/00

(52) U.S. Cl. 136/255; 136/249; 438/74

(57) ABSTRACT

A multi-junction solar cell assembly includes a transparent substrate and a transparent conductive coating formed on the transparent substrate. The transparent conductive coating includes gallium nitride. The solar cell assembly also includes a plurality of gallium indium nitride junction layers formed successively on the transparent conductive coating, and a metallization layer formed on the plurality of gallium indium nitride junction layers.

### BACKGROUND OF THE INVENTION

The present invention relates generally to solar cells, and more specifically to solar cells including transparent conductive coatings.

Solar cells typically include a collector grid for conducting solar photon-generated currents from the surface of the cell. Collector grids have conventionally been metallic grids that can obscure the solar cell, resulting in a loss of efficiency. To reduce obscuration, some known solar cells use a transparent conductive coating (TCC), such as gallium nitride (GaN), as the collector grid. Currently, TCCs are being used to improve the efficiency of gallium arsenide (GaAs) solar cells. Some known GaAs solar cells include a transparent substrate, a TCC formed on the transparent substrate, and the GaAs cell formed on the TCC. Such an arrangement eliminates the need for a separate cover glass and a cover glass adhesive that may darken and thereby reduce efficiency through solar obscuration. However, even GaAs solar cells including TCCs typically do not operate above about 30 percent efficiency. Additionally, a lattice mismatch between the TCC and the GaAs solar cell may cause dislocations or defects that further reduce efficiency.

### SUMMARY OF THE INVENTION

In one aspect, a multi-junction solar cell assembly includes a transparent substrate and a transparent conductive coating formed on the transparent substrate, wherein the transparent conductive coating includes GaN. The solar cell assembly also includes a plurality of gallium indium nitride (GalnN) junction layers formed successively on the transparent conductive coating, and a metallization layer formed on the plurality of GaInN junction layers.

In another aspect, a method is provided of forming a multi-junction solar cell assembly including the steps of forming a transparent conductive coating including GaN on a sapphire substrate, forming a plurality of GaInN junction layers on the transparent conductive coating, and forming a metallization layer on the plurality of GaInN junction layers.

In yet another aspect, a solar cell assembly includes a transparent substrate and a transparent conductive coating formed on the transparent substrate, wherein the transparent conductive coating includes GaN. The solar cell assembly also includes a GaInN junction layer formed directly on the transparent conductive coating in intimate contact with the transparent conductive coating, and a metallization layer formed on the GaInN junction layer.

In even another aspect, a multi-junction solar cell assembly includes a substrate having a first side and a second side opposite the first side, a metallization layer formed on the first side of the substrate, and a collector grid formed on the second side of the substrate. The multi-junction solar cell assembly also includes a plurality of GaInN junction layers formed successively on the collector grid, and a glass cover on the plurality of GaInN junction layers.

Other features of the present invention will be in part apparent and in part pointed out hereinafter.

### BRIEF DESCRIPTION OF THE DRAWINGS

FIG. 1 is an elevation of a solar cell assembly of the present invention;

FIG. 2 is an elevation of one embodiment of a transparent conductive coating formed on a substrate of the solar cell assembly shown in FIG. 1;

FIG. 3 is an elevation of an alternative embodiment of the transparent conductive coating formed on the substrate;

FIGS. 4A-C are elevations illustrating steps for forming another alternative embodiment of the transparent conductive coating on the substrate; and

FIG. 5 is an elevation of an alternative solar cell assembly of the present invention.

Corresponding reference characters indicate corresponding parts throughout the several views of the drawings.

### DETAILED DESCRIPTION OF THE PREFERRED EMBODIMENT

Referring now to the drawings, and more specifically to FIG. 1, a solar cell assembly of the present invention is designated in its entirety by the reference numeral 20. The solar cell assembly 20 generally includes a transparent substrate 22, a transparent conductive coating (TCC, generally designated by 24) formed on and in intimate contact with the transparent substrate, a plurality of GaInN junction layers 26 formed successively on the TCC, and a metallization layer 28 formed on the GaInN junction layers. The solar cell assembly 20 also includes a conventional metal current collector bus 30. Although the metal current collector bus 30 is shown in FIG. 1 in a back contact solar cell arrangement, the bus 30 may alternatively be arranged as a front contact without departing from the scope of the present invention. In some embodiments, a GaN junction layer 32 is formed on the TCC 24 between the TCC and the GaInN junction layers 26. Additionally, in some embodiments, an indium nitride (InN) junction layer 34 is formed on the GaInN junction layers 26 between the metallization layer 28 and the GaInN junction layers. A tunnel diode 35 is formed between each successive junction layer 26, between the junction layers 26 and the GaN junction layer 32 if included in the assembly 20, and between the junction layers 26 and the InN junction layer 34 if included in the assembly.

The substrate 22 may be formed from any suitable transparent material. Although other transparent materials may be used without departing from the scope of the present invention (e.g., zinc oxide (ZnO) or GaN), in one embodiment the transparent substrate 22 is sapphire. In one embodiment, the substrate 22 is entirely transparent to electromagnetic radiation.

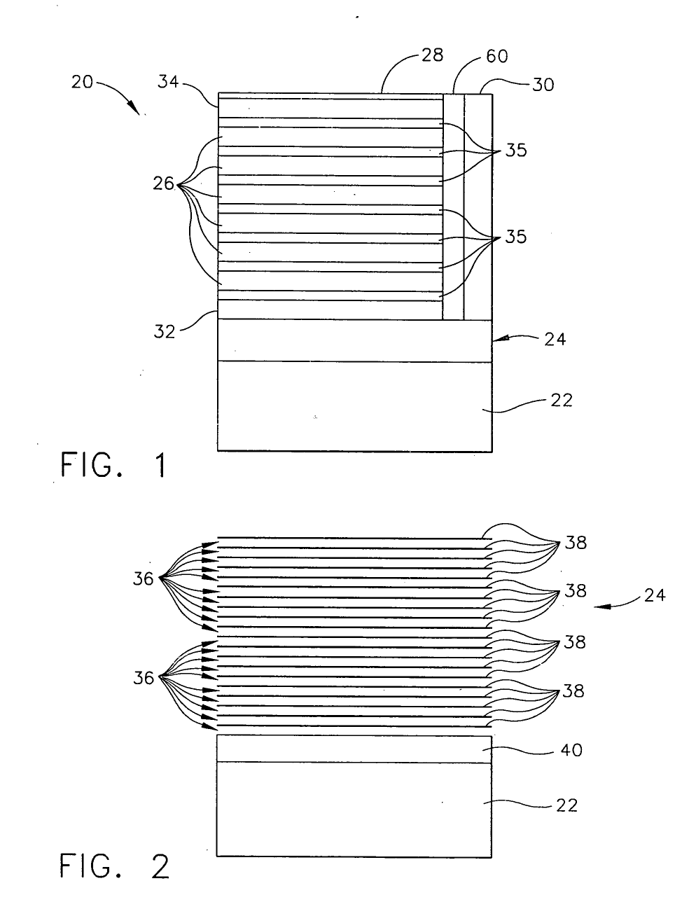

The TCC 24, commonly referred to as a front collector, collects electrical power from the GaInN junction layers 26 (in addition to the junction layers 32, 34 if either are included in the assembly 20) and directs the electrical power to the metal current collector bus 30, as described below. In one embodiment, the TCC 24 is entirely transparent to electromagnetic radiation. The TCC 24 may be formed by any suitable method. For example as illustrated in FIG. 2, the TCC 24 is formed as a plurality of quantum wells (generally designated by 36) formed between a plurality of alternating layers 38 of two lattice matched, wide band gap crystalline materials, such as GaN and aluminum gallium nitride (AlGaN). For example, the TCC 24 may be formed as a plurality of alternating layers 38 of GaN and Al_{0.1}Ga_{0.9}N, each having a thickness of about 100 Angstroms. The alternating layers 38 of GaN and AlGaN are formed on the transparent substrate 22. Each quantum well 36 is formed at a corresponding interface between adjacent layers of the alternating layers 38 of GaN and AlGaN. In some embodiments, a buffer layer 40 of GaN is formed on the transparent substrate 22, and the alternating layers 38 of GaN and AlGaN are formed on the GaN buffer layer. Although the GaN buffer layer 40 may have any suitable thickness without departing from the scope of the present invention, in one embodiment the GaN buffer layer has a thickness of about 1.5 microns. Additionally, the last layer formed on the substrate 22 of the alternating layers 38 of GaN and AlGaN may be a layer of GaN to facilitate forming the GaInN junction layers 26 (in addition to the GaN junction layer 32, if it is included in the assembly 20) on the TCC 24.

The interface between two lattice matched, wide band gap crystalline materials may provide a generally higher electron mobility than the electron mobility in the same bulk materials for the same electron concentrations. For materials such as AlGaN and GaN, such two-dimensional quantum well structures may have electron mobilities as high as about 800 square centimeters per volt-second (cm²N-s), in contrast to the electron mobility of a similarly doped (typically silicon is used for the dopant) bulk GaN may only be about 300 cm²N-s. Both AlGaN and GaN may also have relatively wide band gaps of about 6.2 eV and about 3.4 eV, respectively, in addition to high optical transparency.

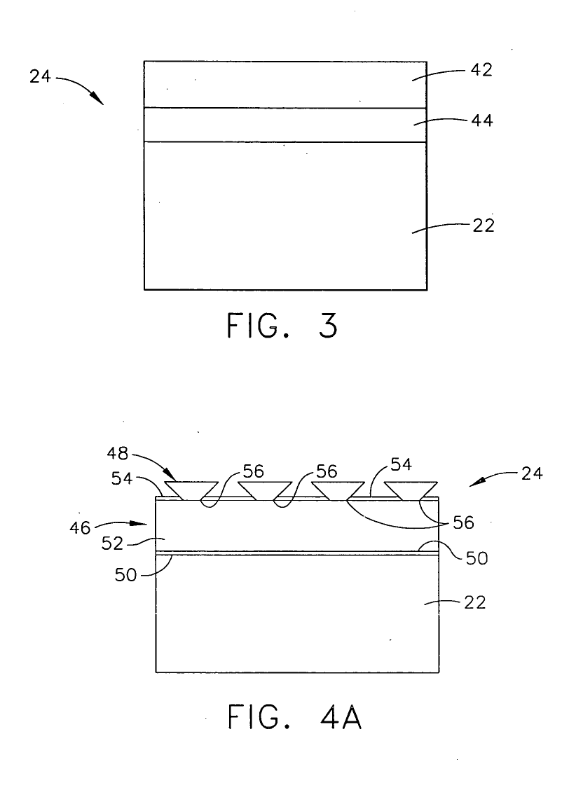

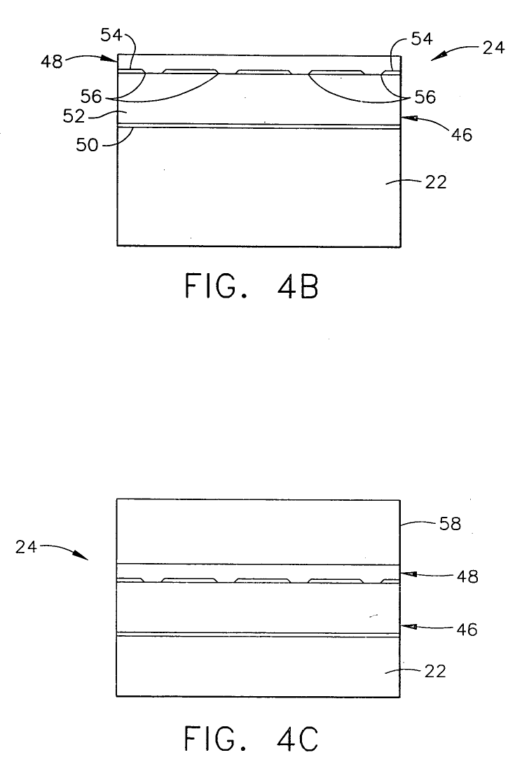

As illustrated in FIG. 3, the TCC 24 may alternatively be formed from a bulk crystalline material, such as a layer 42 of GaN (e.g., a single n-type doped layer of GaN having a thickness of about 2 microns). The GaN layer 42 is formed on the transparent substrate 22. In some embodiments, a buffer layer 44 of GaN is formed on the transparent substrate 22, and the GaN layer 42 is formed on the GaN buffer layer. Although the GaN buffer layer 44 may have any suitable thickness without departing from the scope of the present invention, in one embodiment the GaN buffer layer has a thickness of about 1.5 microns. Bulk crystalline materials such as GaN may generally have good sheet resistance with a low carrier concentration, and therefore may exhibit generally low absorption by free carriers. For example, in one embodiment free carrier absorption by the GaN layer 42 is at most about 10 percent at visible wavelengths.

As illustrated in FIGS. 4A-C, another method of forming the TCC 24 using a crystalline material, such as GaN, includes forming a nucleation layer (generally designated by 46) and a lateral epitaxial overgrowth layer (generally designated by 48) on the transparent substrate 22 to reduce defects in the TCC caused by a lattice mismatch between the TCC and the substrate. More specifically, as illustrated in FIG. 4A the nucleation layer 46 includes a coating 50 formed directly on the transparent substrate 22 in intimate contact with the substrate. Although other materials for the coating 50 may be used without departing from the scope of the present invention, in one embodiment the coating is aluminum nitride (AlN) having an exemplary thickness of about 1.5 microns. A seed layer 52 of GaN is formed on the coating 50 to complete the nucleation layer 46. In one embodiment, the nucleation layer 46 has a thickness of about 500 angstroms or less. A mask layer 54 having a plurality of openings 56 is epitaxially formed on the nucleation layer 46. The mask layer 54 may be formed from any suitable material (e.g., silicon dioxide [SiO₂], aluminum oxide [Al₂O₃]) and to any suitable thickness (e.g., about 200 nanometers).

As illustrated in FIGS. 4A and 4B, when growth of GaN from the seed layer 52 is resumed, the GaN grows out of the openings 56 to form the lateral epitaxial overgrowth layer 48. More specifically, as shown in FIG. 4A GaN first grows in a generally vertical (as seen in the Figs.) direction. However, as shown in FIG. 4B growth of the GaN later changes to a generally lateral (as seen in the Figs.) growth direction to merge with the overgrowth of adjacent openings of the openings 56. Accordingly, as GaN is grown to form the lateral epitaxial overgrowth layer 48, the mask layer 54 blocks threading dislocations associated with the lattice mismatch between the transparent substrate 22 and the GaN of the TCC 24. Additionally, when the growth of GaN changes to a generally lateral growth direction, propagation of the threading dislocations also changes from a generally vertical direction to a generally lateral direction. This change prevents the dislocations from propagating into subsequent growth layers formed on the lateral epitaxial overgrowth layer 48. Accordingly, generally defect-free layers of GaN can be formed on the lateral epitaxial overgrowth layer 48 to generally form the TCC 24 on the transparent substrate 22 without defects, despite a lattice mismatch between the TCC and the substrate. As illustrated in FIG. 4C, a defect-free GaN layer 58 is formed on the lateral epitaxial overgrowth layer 48 to complete the TCC 24.

Referring again to FIG. 1, the GaInN junction layers 26 are photovoltaic such that they generate electrical power by absorbing electromagnetic radiation. The GaInN junction layers 26 are formed successively on the TCC 24 by conventional techniques. As described above, in some embodiments the GaN junction layer 32 is formed on the TCC 24 between the TCC and the GaInN junction layers 26. If the TCC 24 has been formed as the plurality of quantum wells 36 (FIG. 2), a first layer of the plurality of GaInN junction layers 26 (or alternatively the GaN junction layer 32 if it is included in the assembly 20) is formed directly on the last GaN layer of the alternating layers 38 (FIG. 2) in intimate contact with the last GaN layer.

Although each of the GaInN junction layers 26 may have other gallium and Indium contents without departing from the scope of the present invention, in one embodiment each layer of the GaInN junction layers has a gallium content of between about 90 wt % and about 10 wt %, and an indium content of between about 90 wt % and about 10 wt %. The contents of gallium and indium within each layer of the GaInN junction layers 26 determine the band gap of the particular layer. The band gap of InN is about 0.7 eV, and as discussed above the band gap of GaN is about 3.4 eV. Accordingly, each layer of the GaInN junction layers 26 has a band gap of between about 0.7 eV and about 3.4 eV, depending on the gallium and indium contents of the particular layer. The band gaps of some or all of the GaInN junction layers 26 can thus be selected to vary across a range of band gaps between about 0.7 eV and about 3.4 eV to produce a multi-junction photovoltaic construct (including the junction layers 32, 34 if they are included in the assembly 20) capable of absorbing electromagnetic radiation over the selected range of band gaps. Accordingly, a wide spectrum of wavelengths from the ultraviolet to the infrared can be absorbed by the GaInN junction layers 26 (and the junction layers 32, 34 if they are included in the assembly 20), possibly resulting in an increase in efficiency of the solar cell assembly 20 over known prior art solar cells. In one embodiment, the solar cell assembly is anticipated to have an efficiency greater than about 30%. In another embodiment, the solar cell assembly is anticipated to have an efficiency between about 50% and about 70%.

In one embodiment, each successive layer of the GaInN junction layers 26 has a gallium content less than the previous layer of the GaInN junction layers and an indium content greater than the previous layer, such that each successive layer has a band gap less than the previous layer. In such an embodiment wherein each successive layer of the GaInN junction layers 26 has a band gap less the previous layer, the GaInN junction layers (and the junction layers 32, 34 if included in the assembly 20) form a multi-junction photovoltaic construct having generally continuous, smoothly changing narrow band gaps across the bulk of the solar spectrum, and more specifically across band gaps of about 3.4 eV to about 0.7 eV. Additionally, when the GaN junction layer 32 is included in the assembly 20, the higher gallium content of the layer of the junction layers 26 that is formed directly on the GaN junction layer 32 may facilitate overcoming a lattice mismatch between the layer 32 and the layer 26 formed directly thereon. Similarly, when the InN junction layer 34 is included in the assembly 20, the higher indium content of the layer of the junction layers 26 that the InN junction layer 34 is formed directly on may facilitate overcoming a lattice mismatch between the layer 34 and the layer 26 that the layer 34 is formed directly on. Alternatively, each successive layer of the GaInN junction layers 26 may have a gallium content greater than the previous layer and an indium content less than the previous layer, such that each successive layer has a band gap greater than the previous layer. In such an embodiment wherein each successive layer of the GaInN junction layers 26 has band gap greater than the previous layer, the InN junction layer 34 may be formed on the TCC 24 between the TCC and the GaInN junction layers and the GaN junction layer 32 may be formed on the GaInN junction layers 26 between the metallization layer 28 and the GaInN junction layers.

Additionally, it should be understood that the contents of gallium and indium, as well as the band gaps, of some or all of the GaInN junction layers 26 may be about equal and/or may vary randomly, such that any composition, combination, configuration, and/or arrangement of each of the GaInN junction layers may be used without departing from the scope of the present invention.

Although the GaInN junction layers 26 may have other thicknesses without departing from the scope of the present invention, in one embodiment each layer of the GaInN junction layers has a thickness of between about 0.2 microns and about 1.0 microns. Additionally, in one embodiment each successive layer of the GaInN junction layers 26 has a thickness greater than a thickness of the previous layer of the GaInN junction layers. The thickness of the layers 26 may be selected depending upon an absorption coefficient of the layers 26 to maximize a number of energetic photons absorbed and thereby achieve a desired efficiency and/or performance of the assembly 20.

The metal current collector bus 30 is well known in the art and receives electrical power from the TCC 24 that the TCC has collected from the GaInN junction layers 26 (in addition to the junction layers 32, 34 if either are included in the assembly 20). The metal current collector bus 30 is formed on the TCC 24 in intimate physical and electrical contact with the TCC by conventional masking and deposition techniques, and may be formed from any suitable material and/or may be formed at any suitable location on the TCC 24. For example, in one embodiment the metal current collector bus 30 is silver. Other examples of the bus 30 include gold, aluminum, platinum, palladium, and high melting point indium allows, such as 97:3 indium-silver and 77.2:20:2.8 tin-indium-silver. The bus 30 may also include a thin layer of chromium, titanium, or other suitable coating thereon to enhance adhesion and prevent diffusion of the bus 30 into the substrate 22. The metal current collector bus 30 may be electrically isolated from the plurality of GaInN junction layers (as well as the junction layers 32, 34 if they are included in the assembly 20) by a dielectric 60 (e.g., SiO₂ or Al₂O₃) formed in one embodiment by conventional masking and deposition techniques.

The metallization layer 28 is well known in the art and may be used for infrared reflectance as well as electrical conductance, for example, for electrically connecting the solar cell assembly 20 to another solar cell assembly. The metallization layer 28 is formed on the plurality of GaInN junction layers 26 by conventional techniques, and may be formed from any material suitable for infrared reflectance and/or electrical conductance. Although other materials (e.g., silver, gold, platinum, palladium, or high melting point indium alloys, such as 97:3 indium-silver or 77.2:20:2.8 tin-indium-silver) may be used to form the metallization layer 28 without departing from the scope of the present invention, in one embodiment the metallization layer 28 is aluminum. The metallization layer 28 may also include a thin layer of chromium, titanium, or other suitable coating thereon to enhance adhesion and prevent diffusion of the layer 28 into the substrate 22. As described above, in some embodiments the InN junction layer 34 is formed on the GaInN junction layers 26 between the metallization layer 28 and the GaInN junction layers.

In operation, electromagnetic radiation propagates through the transparent substrate 22, the TCC 24, the GaN junction layer 32 if included in the assembly 20, the GaInN junction layers 26, and the InN junction layer 34 if included in the assembly 20. The junction layers 26, 32, 34 absorb some of the electromagnetic radiation propagating therethrough as electrical power. Electromagnetic radiation not initially absorbed by the junction layers 26, 32, 34 is reflected off the metallization layer 28 and propagates through the junction layers 26, 32, 34 in the opposite direction, some of which is absorbed by the junction layers 26, 32, 34 as more electrical power. The TCC 24 collects the electrical power generated by the junction layers 26, 32, 34 and directs it to the metal current collector bus 30, which receives the generated power for eventual storage and/or use.

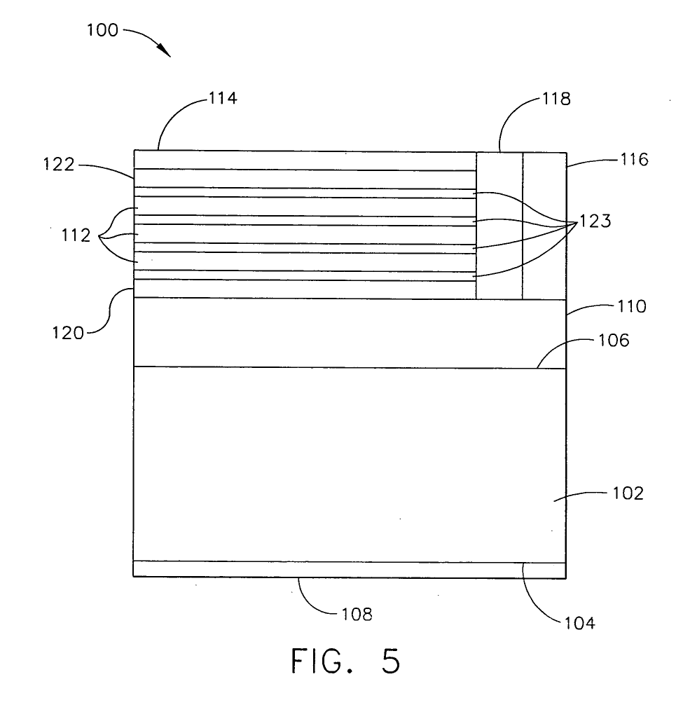

An alternative embodiment of the solar cell assembly of the present invention is illustrated in FIG. 5. More specifically, a solar cell assembly designated in its entirety by the reference numeral 100 generally includes a substrate 102 having a first side 104 and a second side 106 opposite the first side, a metallization layer 108 formed on the first side of the substrate, a collector grid 110 formed on the second side of the substrate, a plurality of GaInN junction layers 112 formed successively on the collector grid, and a glass cover 114 on the GaInN junction layers. The solar cell assembly 100 may also include a metal current collector bus 116 and a dielectric 118. Although the metal current collector bus 116 is shown in FIG. 5 in a back contact solar cell arrangement, the bus 116 may alternatively be arranged as a front contact without departing from the scope of the present invention. In some embodiments, a GaN junction layer 120 is formed on the collector grid 110 between the collector grid and the GaInN junction layers 112. Additionally, in some embodiments an InN junction layer 122 is formed on the GaInN junction layers 112 between the metallization layer 108 and the GaInN junction layers. A tunnel diode 123 is formed between each successive junction layer 112, between the junction layers 112 and GaN junction 120 if included in the assembly 100, and between the junction layers 112 and the InN junction layer 122 if included in the assembly.

The substrate 102 may be any suitable substrate, for example transparent substrates such as sapphire, GaN, or ZnO, or non-transparent substrates such as germanium. The GaInN junction layers 112 are generally equivalent in form and function to the GaInN junction layers 26 (FIG. 1) described above, and accordingly the layers 112 may be formed on the collector grid 110 in any suitable configuration and by conventional techniques as described above. The metallization layer 108, the metal current collector bus 116, and the dielectric 1 18 are well known in the art and generally equivalent in form and function to the metallization layer 28, the metal current collector bus 30, and the dielectric 60, respectively, described above, and therefore will not be described in further detail herein. The collector grid 110 is well known in the art and may be any suitable collector grid, such as the TCC 24 described above or another suitable transparent conductive coating, or a metallic collector grid (e.g., aluminum, gold, sliver, platinum, or high melting point indium alloys such as 97:3 indium-silver or 77.2:20:2.8 tin-indium-silver). The collector grid 110 may also include a thin layer of chromium, titanium, or other suitable coating thereon to enhance adhesion and prevent diffusion of the grid into the substrate 102.

Additionally, the glass cover 114 is well known in the art and may be any suitable glass cover, such as a Corning 0213 glass cover, commercially available from Corning Glass of Corning, N.Y. The glass cover 114 may be attached to the plurality of GaInN junction layers 112 in any suitable manner (e.g., with adhesive).

In operation, electromagnetic radiation propagates through the glass cover 114, the InN junction layer 122 if included in the assembly 100, the GaInN junction layers 112, the GaN junction layer 120 if included in the assembly, and the substrate 102. The junction layers 122, 112, 120 absorb some of the electromagnetic radiation propagating therethrough as electrical power. Electromagnetic radiation not initially absorbed by the junction layers 122, 112, 120 is reflected off the metallization layer 108 and propagates through the junction layers 122, 112, 120 in the opposite direction, some of which is absorbed by the junction layers 122, 112, 120 as more electrical power. The collector grid 110 collects the electrical power generated within the junction layers 122, 112, 120 and directs it to the metal current collector bus 116, which receives the generated power for eventual storage and/or use.

The above-described solar cell assembly is cost-effective, efficient, and reliable for generating electrical power from electromagnetic radiation. More specifically, by creating a multi-junction photovoltaic construct from a plurality of junction layers each having a band gap of between about 0.7 eV and 3.4 eV, the solar cell of the present invention is capable of absorbing electromagnetic radiation over a wide spectrum of wavelengths from the ultraviolet to the infrared, possibly resulting in an increase of efficiency over known prior art solar cells. Furthermore, when some or all of the junction layers have a unique band gap, the junction layers can be arranged to form a multi-junction photovoltaic construct having generally continuous, smoothly changing narrow band gaps across the bulk of the solar spectrum, possibly increasing the efficiency of the assembly even further. Additionally, forming the junction layers on a TCC eliminates a lattice mismatch problem between the junction layers and the substrate of the solar cell assembly, and additionally eliminates the need for a conventional metallic collector grid that can cause solar obscuration and thereby reduce efficiency. Even further, the use of a transparent substrate eliminates the need for a separate cover glass and a cover glass adhesive that may darken and thereby reduce efficiency through solar obscuration.

Although the solar cell assemblies of the present invention are described and illustrated herein as multi-junction solar cells having a plurality of GaInN junction layers 26, it should be understood that the solar cell assemblies may including only one GaInN junction layer 26. Accordingly, practice of the present invention is not limited to multi-junction solar cells.

Exemplary embodiments of solar cell assemblies are described above in detail. The assemblies are not limited to the specific embodiments described herein, but rather, components of each assembly may be utilized independently and separately from other components described herein. Each solar cell assembly component can also be used in combination with other solar assembly components.

When introducing elements of the present invention or the preferred embodiment(s) thereof, the articles “a”, “an”, “the” and “said” are intended to mean that there are one or more of the elements. The terms “comprising”, “including” and “having” are intended to be inclusive and mean that there may be additional elements other than the listed elements.

As various changes could be made in the above constructions without departing from the scope of the invention, it is intended that all matter contained in the above description or shown in the accompanying drawings shall be interpreted as illustrative and not in a limiting sense.

1. A multi-junction solar cell assembly comprising:
a transparent substrate;
a transparent conductive coating formed on the transparent substrate, said transparent conductive coating comprising gallium nitride;
a plurality of gallium indium nitride junction layers formed successively on the transparent conductive coating; and
a metallization layer formed on the plurality of gallium indium nitride junction layers.

2. A multi-junction solar cell assembly in accordance with claim 1 wherein the transparent substrate is selected from a group of transparent substrates consisting of sapphire, zinc oxide, and gallium nitride.

3. A multi-junction solar cell assembly in accordance with claim 1 further comprising an indium nitride junction layer formed on the plurality of gallium indium nitride junction layers between the metallization layer and the plurality of gallium indium nitride junction layers.

4. A multi-junction solar cell assembly in accordance with claim 1 further comprising a gallium nitride junction layer formed on the transparent conductive coating between the transparent conductive coating and the plurality of gallium Indium nitride junction layers.

5. A multi-junction solar cell assembly in accordance with claim 1 wherein each layer of the plurality of gallium indium nitride junction layers has a thickness of between about 0.2 microns and about 1.0 microns.

6. A multi-junction solar cell assembly in accordance with claim 1 wherein each successive layer of the plurality of gallium indium nitride junction layers has a thickness greater than a thickness of the immediately preceding layer of the plurality of gallium indium nitride junction layers.

7. A multi-junction solar cell assembly in accordance with claim 1 wherein each layer of the plurality of gallium indium nitride junction layers has a gallium content of between about 90 wt % and about 10 wt % and an indium content of between about 90 wt % and about 10 wt %.

8. A multi-junction solar cell assembly in accordance with claim 1 wherein each successive layer of the plurality of gallium indium nitride junction layers has a gallium content less than the immediately preceding layer of the plurality of gallium indium nitride junction layers and an indium content greater than the immediately preceding layer of the plurality of gallium indium nitride junction layers.

9. A multi-junction solar cell assembly in accordance with claim 1 wherein each layer of the plurality of gallium indium nitride junction layers has a band gap of between about 0.7 eV and about 3.4 eV.

10. A multi-junction solar cell assembly in accordance with claim 1 wherein each successive layer of the plurality of gallium indium nitride junction layers has a band gap less than the band gap of the immediately preceding layer of the plurality of gallium indium nitride junction layers.

11. A multi-junction solar cell assembly in accordance with claim 1 wherein the transparent conductive coating comprises:
a nucleation layer formed on the transparent substrate;
a lateral epitaxial overgrowth layer of gallium nitride formed on the nucleation layer; and
a defect-free gallium nitride layer formed on the lateral epitaxial overgrowth layer.

12. A multi-junction solar cell assembly in accordance with claim 11 wherein the nucleation layer comprises:
an aluminum nitride coating formed directly on the transparent substrate in intimate contact with the transparent substrate; and
a seed layer of gallium nitride formed on the aluminum nitride coating.

13. A multi-junction solar cell assembly in accordance with claim 1 wherein the transparent conductive coating comprises:
a plurality of alternating layers of gallium nitride and aluminum gallium nitride; and
a plurality of quantum wells, each quantum well of the plurality of quantum wells formed at a corresponding interface between adjacent layers of gallium nitride and aluminum gallium nitride of the plurality of alternating layers of gallium nitride and aluminum gallium nitride.

14. A multi-junction solar cell assembly in accordance with claim 13 wherein a first gallium indium nitride junction layer of the plurality of gallium indium nitride junction layers is formed directly on a last gallium nitride layer of the plurality of alternating layers of gallium nitride and aluminum gallium nitride in intimate contact with the last gallium nitride layer of the plurality of alternating layers of gallium nitride and aluminum gallium nitride.

15. A multi-junction solar cell assembly in accordance with claim 1 wherein the transparent conductive coating comprises a gallium nitride layer formed on the transparent substrate.

16. A multi-junction solar cell assembly in accordance with claim 1 further comprising a metal current collector bus for receiving electrical power collected from the plurality of gallium indium nitride junction layers by the transparent conductive coating.

17. A multi-junction solar cell assembly in accordance with claim 1 wherein said transparent substrate is entirely transparent to electromagnetic radiation.

18. A multi-junction solar cell assembly in accordance with claim 1 wherein said transparent conductive coating is entirely transparent to electromagnetic radiation.

19. A method of forming a multi-junction solar cell assembly comprising the steps of:
forming a transparent conductive coating including gallium nitride on a substrate;
forming a plurality of gallium indium nitride junction layers on the transparent conductive coating; and
forming a metallization layer on the plurality of gallium indium nitride junction layers.

20. A method in accordance with claim 19 further comprising forming an Indium nitride junction layer on the plurality of gallium indium nitride junction layers between the metallization layer and the plurality of gallium indium nitride junction layers.

21. A method in accordance with claim 19 further comprising forming a gallium nitride junction layer on the transparent conductive coating between the transparent conductive coating and the plurality of gallium indium nitride junction layers.

22. A solar cell assembly comprising:
a transparent substrate;
a transparent conductive coating formed on the transparent substrate, said transparent conductive coating comprising gallium nitride;
a gallium indium nitride junction layer formed directly on the transparent conductive coating in intimate contact with the transparent conductive coating; and
a metallization layer formed on the gallium indium nitride junction layer.

23. A multi-junction solar cell assembly comprising:
a substrate having a first side and a second side opposite the first side;
a metallization layer formed on the first side of the substrate;
a collector grid formed on the second side of the substrate;
a plurality of gallium indium nitride junction layers formed successively on the collector grid; and
a glass cover on the plurality of gallium indium nitride junction layers.
